(19) United States
(12) Patent Application Publication
(10) Pub. No.: US 2016/0216317 A1
(43) Pub. Date: Jul. 28, 2016

(54) BUILT-IN TEST STRUCTURE FOR A RECEIVER

(71) Applicant: QUALCOMM, Incorporated, San Diego, CA (US)

(72) Inventors: Minhan Chen, Cary, NC (US); Kenneth Luis Arcudia, Cary, NC (US); Bupesh Pandita, Raleigh, NC (US)

(21) Appl. No.: 14/603,025

(22) Filed: Jan. 22, 2015

(51) Int. Cl. G01R 31/28; H04B 17/20

(52) U.S. Cl. CPC G01R 31/2884; H04B 17/20

(57) ABSTRACT

In one embodiment, a method for operating a receiver having a first receiver input and a second receiver input is described herein. The method comprises receiving a data signal via the first and second receiver inputs in a mission mode, AC-coupling the received data signal to an amplifier, and amplifying the AC-coupled data signal using the amplifier. The method also comprises receiving one or more test signals via one or both of the first and second receiver inputs in a test mode, DC-coupling the received one or more test signals to a test receiver, and determining whether there are one or more defects based on the one or more test signals received by the test receiver.

### BACKGROUND

1. Field

Aspects of the present disclosure relate generally to test structures, and more particularly, to a built-in test structure for a receiver.

2. Background

A high-speed communication system may be used to provide high-speed data communication between first and second devices (e.g., in the gigahertz range). To do this, the communication system may comprise a transmitter at the first device and a receiver at the second device. In operation, the transmitter transmits high-speed data to the receiver over one or more channels. For example, the first and second devices may be on separate chips mounted on a board, in which the communication system comprises a differential channel (e.g., pair of traces) and AC-coupling capacitors on the board. In this example, the transmitter may transmit high-speed data to the receiver over the differential channel and AC-coupling capacitors. The communication system may have a built-in test function to detect defects of elements on the board and front-end elements on the chip of the receiver.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

According to a first aspect, a receiver is provided herein. The receiver comprises an amplifier having a first input and a second input, a first AC-coupling capacitor coupled between a first receiver input and the first input of the amplifier, and a second AC-coupling capacitor coupled between a second receiver input and the second input of the amplifier. The receiver also comprises a test receiver having a first input and a second input, wherein the first input of the test receiver is coupled between the first receiver input and the first AC-coupling capacitor, and the second input of the test receiver is coupled between the second receiver input and the second AC-coupling capacitor. The receiver further comprises a test engine coupled to the test receiver. In a test mode, the test receiver is configured to receive one or more test signals via one or both of the first and second receiver inputs, and the test engine is configured to determine whether there are one or more defects based on the one or more test signals received by the test receiver. In a mission mode, the amplifier is configured to receive a data signal via the first and second receiver inputs and amplify the received data signal.

A second aspect relates to a receiver. The receiver comprises an amplifier having a first input coupled to a first receiver input and a second input coupled to a second receiver input, a first test receiver having a first input coupled to the first receiver input and a second input coupled to the second receiver input, a second test receiver having a first input coupled to the first receiver input and a second input coupled to the second receiver input, and a test engine coupled to the first and second test receivers. In a first test mode, the first test receiver is configured to receive one or more first test signals via one or both of the first and second receiver inputs, and the test engine is configured to determine whether there are one or more first defects based on the one or more first test signals received by the first test receiver. In a second test mode, the second test receiver is configured to receive one or more second test signals via one or both of the first and second receiver inputs, and the test engine is configured to determine whether there are one or more second defects based on the one or more second test signals received by the second test receiver. In a mission mode, the amplifier is configured to receive a data signal via the first and second receiver inputs and amplify the received data signal.

A third aspect relates to a method for operating a receiver having a first receiver input and a second receiver input. The method comprises receiving a data signal via the first and second receiver inputs in a mission mode, AC-coupling the received data signal to an amplifier, and amplifying the AC-coupled data signal using the amplifier. The method also comprises receiving one or more test signals via one or both of the first and second receiver inputs in a test mode, DC-coupling the received one or more test signals to a test receiver, and determining whether there are one or more defects based on the one or more test signals received by the test receiver.

A fourth aspect relates to an apparatus for operating a receiver having a first receiver input and a second receiver input. The apparatus comprises means for receiving a data signal via the first and second receiver inputs in a mission mode, and means for AC-coupling the received data signal to an amplifier. The apparatus also comprises means for receiving one or more test signals via one or both of the first and second receiver inputs in a test mode, means for DC-coupling the received one or more test signals to a test receiver, and means for determining whether there are one or more defects based on the one or more test signals received by the test receiver.

To the accomplishment of the foregoing and related ends, the one or more embodiments comprise the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1 shows an example of a high-speed communication system.

FIG. 2 shows an example of a receiver with a built-in test structure.

FIG. 3 shows a receiver with a built-in AC/DC test structure according to an embodiment of the present disclosure.

FIG. 4 shows an example of bypass switches for DC-coupling test signals to a receiver according to an embodiment of the present disclosure.

FIG. 5 is a flowchart of a method for operating a receiver with a built-in test structure according to an embodiment of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

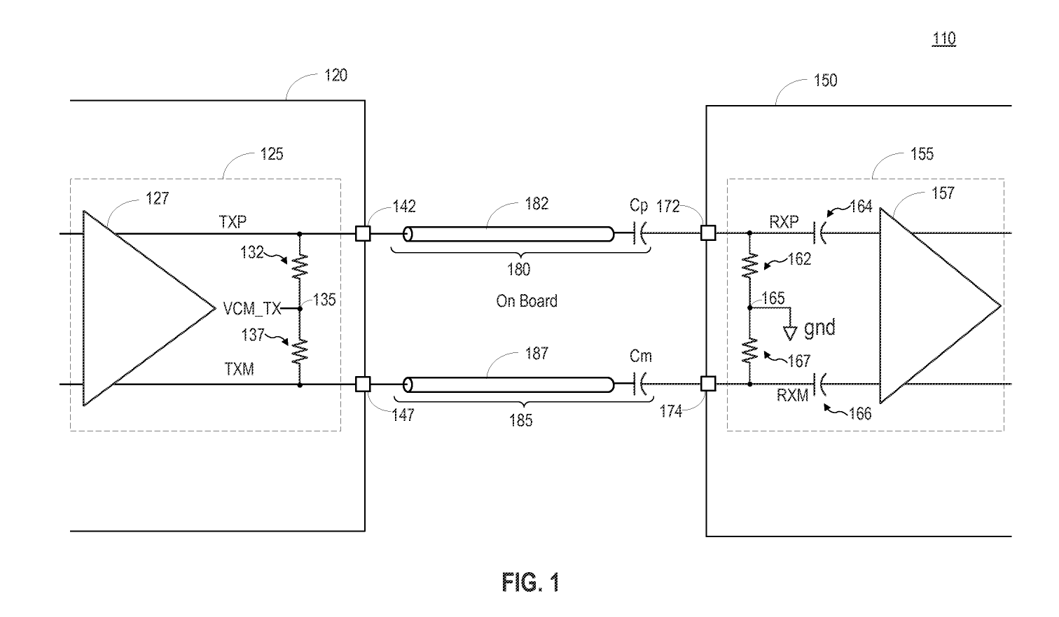

FIG. 1 shows an example of a high-speed communication system 110 (e.g., SERDES communication system) configured to provide high-speed data communication (e.g., in the gigahertz range) between a first device (not shown) on a first chip 120 and a second device (not shown) on a second chip 150. To do this, the communication system 110 comprises a transmitter 125 on the first chip 120 and a receiver 155 on the second chip 150. In operation, the transmitter 125 transmits high-speed serial data to the receiver 155 over one or more channels, as discussed further below.

In the example in FIG. 1, the first and second chips 120 and 150 are mounted on a board (e.g., printed circuit board). In this example, the communication system 110 comprises first and second channels 182 and 187 (e.g., board traces) and a pair of AC-coupling capacitors Cp and Cm on the board. The first and second channels 182 and 187 form a differential channel capable of transferring a high-speed differential data signal from the transmitter 125 on the first chip 120 to the receiver 155 on the second chip 150. The first channel 182 is coupled to onboard AC-coupling capacitor Cp, forming a first signal path 180 between the first and second chips 120 and 150. The second channel 187 (e.g., board trace) is coupled to onboard AC-coupling capacitor Cm forming a second signal path 185 between the first and second chips 120 and 150.

The transmitter 125 comprises a transmit driver 127 configured to receive a differential data signal to be transmitted to the second chip 150, and to drive transmit paths TXP and TXM with the differential data signal. The transmitter 125 also comprises first and second termination resistors 132 and 137 coupled in series between transmit paths TXP and TXM. Each of the termination resistors 132 and 137 may have a resistance approximately equal to 50Ω. A common-mode voltage of VCM_TX is provided at the node 135 between the first and second resistors 132 and 137 (e.g., by a voltage generator on the first chip 120). The common-mode voltage VCM_TX may be used to set the common-mode voltage of the differential data signal transmitted from the transmitter 125.

The communication system 110 may also comprise a first I/O pad 142 for coupling transmit path TXP to the first signal path 180, and a second I/O pad 147 for coupling transmit path TXM to the second signal path 185. It is to be appreciated that the communication system 110 may include additional structures (e.g., pins, bond wires, solder joints, etc.) coupling the first and second I/O pads 142 and 147 to the first and second signal paths 180 and 185, respectively.

The receiver 155 comprises a receive amplifier 157 configured to receive the differential data signal from receive paths RXP and RXM, to amplify the received differential data signal, and to output the amplified data signal to other components (e.g., deserializer for SERDES) on the second chip 150 for further processing. The receiver 155 also comprises third and fourth termination resistors 162 and 167 coupled in series between receive paths RXP and RXM, in which the node 165 between the resistors is grounded, as shown in FIG. 1. Each of the termination resistors 162 and 167 may have a resistance approximately equal to 50Ω to provide a 50-ohm impedance termination at the receiver, which may approximately match a characteristic impedance of the channels 182 and 187. The receiver 155 further comprises a first on-chip AC-coupling capacitor 164 for AC coupling the signal on receive path RXP to a first input of the receive amplifier 157, and a second on-chip AC-coupling capacitor 166 for AC coupling the signal on receive path RXM to a second input of the receive amplifier 157.

The communication system 110 may also comprise a third I/O pad 172 for coupling the first signal path 180 to receive path RXP, and a fourth I/O pad 174 for coupling the second signal path 185 to receive path RXM. It is to be appreciated that the communication system 110 may include additional communication structures (e.g., pins, bond wires, solder joints, etc.) coupling the first and second signal paths 180 and 185 to the third and fourth I/O pads 172 and 174, respectively.

To transmit data from the first chip 120 to the second chip 150, the transmit driver 127 drives transmit paths TXP and TXM with a corresponding differential data signal, in which the data is sent serially. The differential data signal may comprise a first signal transmitted on transmit path TXP and a second signal (e.g., complement of the first signal) transmitted on transmit path TXM. The differential data signal is coupled to the first and second signal paths 180 and 185 on the board by I/O pads 142 and 147. The differential data signal travels across the first and second signal paths 180 and 185 on the board to the second chip 150. The differential data signal is coupled to receive paths RXP and RXM on the second chip 150 by I/O pads 172 and 174, and then AC-coupled to the two inputs of the receive amplifier 157 by on-chip capacitors 164 and 166.

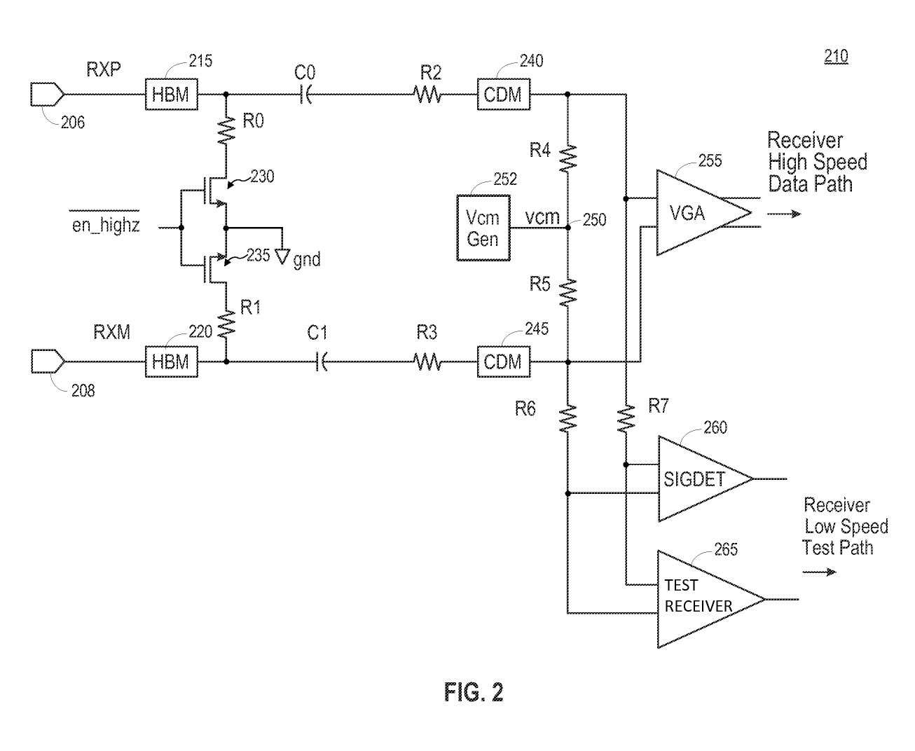

A built-in test function may be used to detect defects (e.g., manufacturing defects) of elements on the board and front-end elements on the chip of the receiver (i.e., second chip 150). In this regard, FIG. 2 shows an example of a receiver 210 with a built-in test function. The receiver 210 may be used to implement the receiver 155 in FIG. 1. The receiver 210 may operate in a mission mode, a high-impedance mode, or a test mode. In the mission mode (also referred to as functional mode), the receiver 210 may receive a high-speed differential data signal from the transmitter 125 over the first and second signal paths 180 and 185 (shown in FIG. 1). In the high-impedance mode, the receiver 210 has a high termination impedance. The test mode is used to detect defects of elements on the board and/or elements in the receiver 210, as discussed further below.

The receiver 210 comprises a first receiver input 206 coupled to receive path RXP and a second receiver input 208 coupled to receive path RXM. The first and second receiver inputs 206 and 208 may be coupled to the first and second signal paths 180 and 185 on the board by I/O pads 172 and 174, respectively (shown in FIG. 1). The receiver 210 also includes a first human body model (HBM) device 215 on receive path RXP, and a second HBM device 220 on receive path RXM. The HBM devices 215 and 220 may be used to provide primary electrostatic discharge (ESD) protection on or near the I/O pads 172 and 174. Each of the HBM devices 215 and 220 may be configured to provide a discharge path from the respective receive path to ground and/or a power rail during an ESD event. For example, each of the HBM devices 215 and 220 may comprise a first clamping diode coupled between the respective receive path and a power rail, and a second clamping diode coupled between the respective receive path and ground.

The receiver 210 also comprises termination resistors R0 and R1, a first switch 230, and a second switch 235. Each of the termination resistors R0 and R1 may have a resistance of 50Ω. Termination resistors R0 and R1 may correspond to termination resistors 162 and 167, respectively, shown in FIG. 1. Termination resistor R0 is coupled between receive path RXP and the first switch 230, and termination resistor R1 is coupled between receive path RXM and the second switch 235. The first switch 230 is coupled between termination resistor R0 and ground, and the second switch 235 is coupled between termination resistor R1 and ground.

The first and second switches 230 and 235 are used to selectively couple the termination resistors R0 and R1 to ground. More particularly, when the first and second switches 230 and 235 are closed, the termination resistors R0 and R1 are coupled to ground. For the example where each of the termination resistors R0 and R1 has a resistance of 50Ω, this provides a 50-ohm termination impedance at the receiver. When the first and second switches 230 and 235 are open, the termination resistors R0 and R1 are no longer coupled to ground, resulting in a high input impedance at the receiver.

In the example shown in FIG. 2, the first and second switches 230 and 235 comprise N-type metal-oxide-semiconductor (NMOS) transistors with an inverse of a high-impedance enable signal (denoted “en_highz”) input to the gates of the NMOS transistors. The first and second switches 230 and 235 are open when the high-impedance enable signal en_highz is logic one, and are closed when the high-impedance enable signal en_highz is logic zero.

In the mission mode, the switches 230 and 235 may be closed to provide, for example, a 50-ohm termination impedance at the receiver. In the high-impedance mode, the switches 230 and 235 are open to provide a high termination impedance at the receiver. The high-impedance mode may be used, for example, when the receiver 210 is one of a plurality of receivers in a multi-lane communication system. In this example, the receiver 210 may be placed in the high-impedance mode when the receiver 210 is not in use (e.g., not receiving data) so that the receiver 210 does not affect one or more other receivers in the communication system that are in the mission mode (e.g., receiving data).

The receiver 210 also comprises a receive amplifier 255, on-chip AC-coupling capacitor C0 on receive path RXP and on-chip AC-coupling capacitor C1 on receive path RXM. The on-chip AC coupling capacitors C0 and C1 may correspond to AC-coupling capacitors 164 and 166, respectively, shown in FIG. 1. In the mission mode, the AC-coupling capacitors C0 and C1 AC couple the received differential data signal to the receive amplifier 255. In other words, the AC-coupling capacitors C0 and C1 pass the AC component of the differential data signal to the receive amplifier 255 while blocking the DC component of the differential data signal. The receive amplifier 255 amplifies the AC-coupled differential data signal and outputs the amplified data signal to other on-chip components (e.g., deserializer for SERDES) for further processing. In the example shown in FIG. 2, the receive amplifier 255 comprises a variable gain amplifier (VGA) having one input coupled to receive path RXP and another input coupled to receive path RXM. Each of the AC-coupling capacitors C0 and C1 may have a capacitance of 2 picofarads (pF) or other capacitance value.

The receiver 210 also includes a first charged device model (CDM) device 240, resistor R2 is series with the first CDM device 240, a second CDM device 245, and resistor R3 is series with the second CDM device 245. The first CDM device 240 and resistor R2 may be used to provide secondary ESD protection on receive path RXP, and the second CDM device 245 and resistor R3 may be used to provide secondary ESD protection on receive path RXM. In one embodiment, each of the CDM devices 240 and 245 may be configured to provide a discharge path from the respective receive path to ground and/or a power rail during an ESD event. For example, each of the CDM devices 240 and 245 may comprise a first clamping diode coupled between the respective receive path and a power rail, and a second clamping diode coupled between the respective receive path and ground. Each of resistors R2 and R3 may have a resistance of between 50Ω and 100Ω or other resistance value.

The receiver 210 further comprises resistors R4 and R5 coupled in series between receive path RXP and receive path RXM after the AC-coupling capacitors C0 and C1. Resistors R4 and R5 may have approximately equal resistance (e.g., 800 KΩ or other resistance value). The receiver 210 further comprises a common-mode voltage generator 252 coupled to the node 250 between resistors R4 and R5. The common-mode voltage generator 252 outputs a voltage vcm to the node 250 to set the common-mode voltage at the inputs of the receive amplifier 255 to a desired voltage level. For example, the common-mode voltage generator 252 may set the common-mode voltage to a level that achieves good amplifying performance for the receive amplifier 255.

The receiver 210 further comprises a signal detector 260 (denoted “SIGDET”) configured to detect a signal on the receive paths RXP and RXM. This information may be used to determine whether a signal is being received by the receiver 210, and to configure components (not shown) on the second chip 150 to process the signal if the signal is detected. The signal detector 260 may also be configured to detect the level (amplitude) of the signal. This information may be used, for example, to adjust the gain of the receive amplifier 255, and/or to distinguish a good signal from a bad signal (a signal that is too low to be reliably received) and/or noise. In the example in FIG. 2, one input of the signal detector 260 is coupled to receive path RXP via resistor R7, and the other input of the signal detector 260 is coupled to receive path RXM via resistor R6. Each of resistors R6 and R7 may have a resistance of 300Ω or other resistance value.

In the mission mode, the receiver 210 may receive a high-speed differential data signal from the transmitter 120 over the first and second signal paths 180 and 185 (shown in FIG. 1). On-chip AC-coupling capacitors C0 and C1 AC couple the received signal to the inputs of the receive amplifier 255, which amplifies the signal and outputs the amplified signal to components (not shown) on the second chip 150 for further processing. Also, in the mission mode, the termination resistors R0 and R1 are coupled to ground by the first and second switches 230 and 235 to provide a termination impedance of 50Ω, which may approximately match a characteristic impedance of the onboard channels 182 and 187. In addition, the common-mode generator 252 provides an internal common-mode voltage to properly bias the inputs of the receive amplifier 255 to achieve good amplifying performance.

As discussed above, the receiver 210 has a built-in test function to detect defects of elements on the board and/or front-end elements on the chip of the receiver (i.e., second chip 150). In this regard, the receiver 210 comprises a test receiver 265 (e.g., amplifier) coupled to receive paths RXP and RXM after the AC-coupling capacitors C0 and C1. More particular, one input of the test receiver 265 is coupled to receive path RXP via resistor R7, and the other input of the test receiver 265 is coupled to receive path RXM via resistor R6.

In the test mode, the receiver 210 may receive one or more test signals from the first and second signal paths 180 and 185. The test signals are AC coupled to the inputs of the test receiver 265 by on-chip AC-coupling capacitors C0 and C1. The test receiver 265 may amplify the test signals and output the test signals to a test engine (not shown in FIG. 2). The test engine may analyze the characteristics of the received test signals to determine defects of onboard elements and/or defects of elements in the receiver 210. This is because different types of defects may affect the characteristics of the received test signals in different ways, allowing the test engine to not only detect a defect, but also determine the type of defect based on the characteristics of the received test signals. In one example, the test engine may test for defects according to a Joint Test Action Group (JTAG) standard, such as the JTAG 1149.6 standard. Also, in the test mode, the termination resistors R0 and R1 are coupled to ground by the first and second switches 230 and 235 to provide a termination impedance of 50Ω. In addition, the common-mode generator 252 is used to generate an internal common-mode voltage that properly biases the inputs of the test receiver 265 to achieve good performance of the test receiver 265.

A drawback of the receiver 210 is that there is no DC signal test path from the I/O pads 172 and 174 to the test receiver 265. This is because the test receiver 265 taps the receive paths RXN and RXP after the AC-coupling capacitors C0 and C1, which block DC signals from the test receiver 265. As a result, the test engine is prevented from performing DC testing, thereby limiting the test engine to AC testing, which may not detect certain types of defects that can be detected using DC testing. Thus, the range of defects that can be detected by the test engine may be reduced.

In addition, the test receiver 265 may have a parasitic capacitance that is coupled to the receive paths RXP and RXM, thereby adding parasitic capacitance to the receive paths RXP and RXM. The parasitic capacitance added by the test receiver 265 reduces the bandwidth of the receive paths RXP and RXM, and therefore reduces the bandwidth of data signals that can be received by the receiver 210 in the mission mode. This may negatively impact the ability of receiver 210 to receive high-speed data signals (e.g., data signals having data rates of one or more gigabits per second).

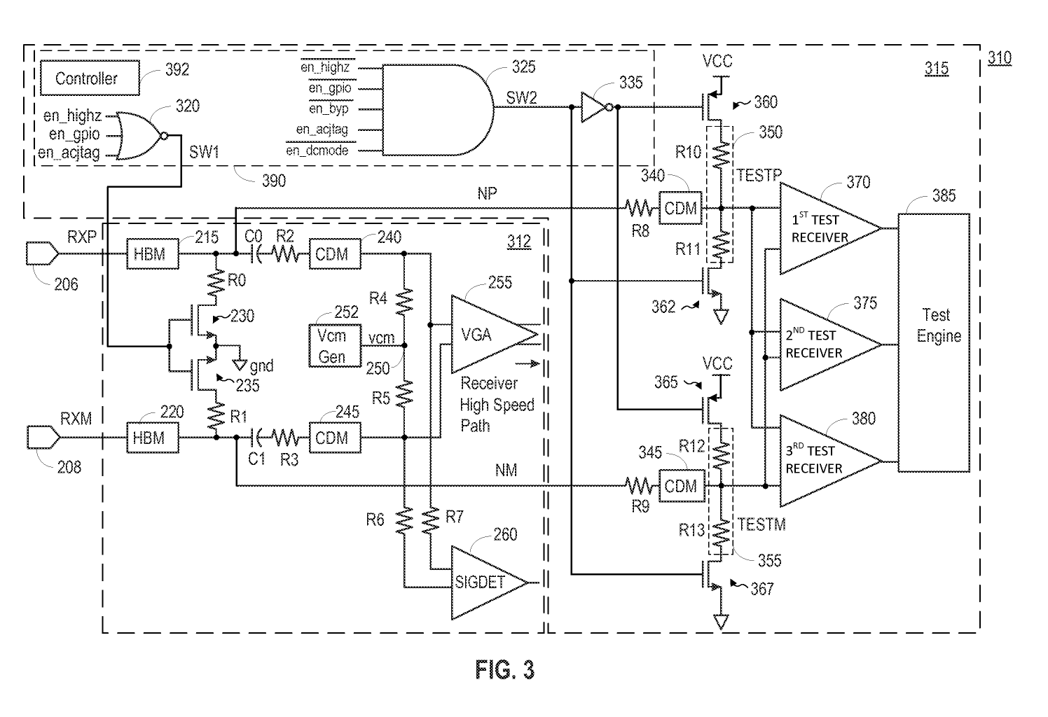

FIG. 3 shows a front-end receiver 310 with a built-in test function according to an embodiment of the present disclosure. The receiver 310 is capable of performing AC tests and DC tests to detect defects (e.g., manufacturing defects) of onboard elements, on-chip elements and/or I/O pads. The receiver 310 may be used to implement the receiver 155 in FIG. 1. The receiver 310 comprises a receive circuit 312 for receiving a high-speed data signal, and a test circuit 315 for detecting defects of onboard elements, on-chip elements and/or I/O pads, as discussed further below.

The receive circuit 312 is configured to receive a high-speed differential data signal from the first and second signal paths 180 and 185 (shown in FIG. 1) in the mission mode (functional mode). In the example shown in FIG. 3, the receive circuit 312 is similar to the receiver 210 in FIG. 2, but without the test receiver 265 coupled to receive paths RXP and RXM after the on-chip AC coupling capacitors C0 and C1. Therefore, the description of the receiver 210 given above is also applicable to the receive circuit 312 in FIG. 3. Accordingly, a detailed description of the receive circuit 312 is omitted here for sake of brevity.

The test circuit 315 comprises a first test path (denoted “NP”) and a second test path (denoted “NM”). The first test path NP taps receive path RXP before AC-coupling capacitor C0, and the second test path NM taps receive path RXM before AC-coupling capacitor C1. As a result, the AC-coupling capacitors C0 and C1 do not block DC signals from the test paths NP and NM. This allows the test circuit 315 to perform both AC and DC tests, as discussed further below.

The test circuit 315 also comprises resistor R8 and a third CDM device 340 on the first test path NP. Resistor R8 is coupled between the third CDM device 340 and receive path RXP, and may have a resistance of 1 KΩ or other resistance value. The test circuit 315 further comprises resistor R9 and a fourth CDM device 345 on the second test path NM. Resistor R9 is coupled between the fourth CDM device 345 and receive path RXM, and may have a resistance of 1 KΩ or other resistance value.

Each of resistors R8 and R9 may be used to isolate parasitic capacitance in the test circuit 315 from the respective receive path to reduce the impact of the test circuit 315 on the bandwidth of the receive circuit 312, as discussed further below. For example, resistor R8 may isolate parasitic capacitance from the third CDM device 340 from receive path RXP, and resistor R9 may isolate parasitic capacitance from the fourth CDM device 345 from receive path RXM.

Each of the third and fourth CDM devices 340 and 345 may be used to provide secondary ESD protection for the respective test path. In this regard, each of the third and fourth CDM devices 340 and 345 may be configured to provide a discharge path (e.g., through a clamping diode) from the respective test path to ground and/or a power rail during an ESD event. For example, each of the CDM devices 340 and 345 may comprise a first clamping diode coupled between the respective test path and a power rail, and a second clamping diode coupled between the respective test path and ground

The test circuit 315 also comprises a first test receiver 370, a second test receiver 375, and a third test receiver 380. Each of the test receivers 370, 375 and 380 may comprise a first input coupled to the first test path NP, and a second input coupled to the second test path NM. In FIG. 3, the first inputs of the test receivers 370, 375 and 380 are coupled to the first test path NP at a first test input node (denoted “TESTP”), and the second inputs of the test receivers 370, 375 and 380 are coupled to the second test path NM at a second test input node (denoted “TESTM”).

The test receivers 370, 375 and 380 may be used to receive test signals in different test modes. For example, the first test receiver 370 may be configured to receive test signals in one test mode according to an AC/DC JTAG standard (e.g., JTAG 1149.6 standard and/or JTAG 1149.1 standard), the second test receiver 375 may be configured to receive test signals in another test mode according to a general purpose I/O (GPIO) test standard, and the third test receiver 380 may be configured to receive test signals in yet another test mode according to a bypass test standard. These exemplary test modes are discussed in further detail below.

The test circuit 315 further comprises a first voltage divider 350 coupled to the first test input TESTP. The first voltage divider 350 is selectively coupled to supply voltage VCC by a third switch 360 and selectively coupled to ground by a fourth switch 362. The first voltage divider 350 comprises resistor R10 coupled between the first test input TESTP and the third switch 360, and resistor R11 coupled between the first test input TESTP and the fourth switch 362. When the third and fourth switches 360 and 362 are closed, the first voltage divider 350 is enabled and establishes a DC bias voltage on the first test input TESTP given by:

V_{DC}=VCC·(R11/(R11+R10)) (1)

where R10 in equation (1) is the resistance of resistor R10, and R11 in equation (1) is the resistance of resistor R11. When the third and fourth switches 360 and 362 are open, the first voltage divider 350 is disabled.

The test circuit 315 further comprises a second voltage divider 355 coupled to the second test input TESTM. The second voltage divider 355 is selectively coupled to supply voltage VCC by a fifth switch 365 and selectively coupled to ground by a sixth switch 367. The second voltage divider 355 comprises resistor R12 coupled between the second test input TESTM and the fifth switch 365, and resistor R13 coupled between the second test input TESTM and the sixth switch 367. When the fifth and sixth switches 365 and 367 are closed, the second voltage divider 355 is enabled and establishes a DC bias voltage on the second test input TESTM given by:

V_{DC}=VCC·(R13/(R12+R13)) (2)

where R12 in equation (2) is the resistance of resistor R12, and R13 in equation (2) is the resistance of resistor R13. When the fifth and sixth switches 365 and 367 are open, the second voltage divider 355 is disabled. In one embodiment, each of the third and fifth switches 360 and 365 comprises a p-type metal-oxide-semiconductor (PMOS) transistor, and each of the fourth and sixth switches 362 and 367 comprises an NMOS transistor, as shown in FIG. 3.

The test circuit 315 further comprises a test engine 385 coupled to the outputs of the test receivers 370, 375 and 380. The test engine 385 is configured to operate in different test modes. In each test mode, the test circuit 385 receives one or more test signals from one of the test receivers 370, 375 and 380 and analyzes the one or more test signals to detect a defect of an element on the board, a defect of an element in the receiver 310 and/or a defect of the I/O pads 172 and 174 (shown in FIG. 1). The test circuit 315 may also comprise a control circuit 390 that controls the switches 230, 235, 360, 362, 365 and 367 to configure the test circuit 315 and the receive circuit 312 for the different test modes, as discussed further below.

As discussed above, the test circuit 315 supports testing in different tests modes. For example, the test circuit 315 may support an AC JTAG test mode, a DC JTAG test mode, an automatic test equipment (ATE) test mode, a GPIO test mode, and a bypass test mode. In this example, the control circuit 390 may configure the test circuit 315 and the receive circuit 312 for the different test modes using signals en_highz, en_gpio, en_acjtag, en_byp, and en_dcmode shown in FIG. 3.

In this regard, the control circuit 390 comprises a controller 392 that controls the logic states of signals en_highz, en_gpio, en_acjtag, en_byp, and en_dcmode according to a selected mode of operation for the receiver. The control circuit 390 also comprises a NOR gate 320 having three inputs configured to receive signals en_highz, en_gpio and en_acjtag, and an output coupled to the gates of the first and second switches 230 and 235 (e.g., NMOS transistors). The output of the NOR gate 320 is denoted “SW1” in FIG. 3. The control circuit 390 also comprises an AND gate 325 having five inputs configured to receive signal en_acjtag and the inverse of signals en_highz, en_gpio, en_byp and en_dcmode, and an output coupled to the gates of the fourth and sixth switches 362 and 367 (e.g., NMOS transistors). The output of the AND gate 325 is denoted “SW2” in FIG. 3. The control circuit 390 further comprises an inverter 335 having an input coupled to the output of the AND gate 325, and an output coupled to the gates of the third and fifth switches 360 and 365 (e.g., PMOS transistors). For ease of illustration, the individual connections between the controller 392 and the inputs of the NOR gate 320 and AND gate 325 are not shown in FIG. 3. The exemplary test modes will now be described in greater detail according to various embodiments of the present disclosure.

AC JTAG Test Mode

This test mode may be used to detect defects of onboard components (e.g., capacitors Cp and Cm). For example, this test mode may be used to detect whether one or both of the onboard AC-coupling capacitors Cp and Cm (shown in FIG. 1) are missing, as discussed further below.

In this test mode, the controller 392 sets signal en_acjtag to logic one and sets each of signals en_dcmode, en_highz, en_gpio and en_byp to logic zero. As a result, the output (SW1) of the NOR gate 320 is logic zero, which turns off (opens) switches 230 and 235, and hence turns off the 50-ohm termination impedance of the receiver. The output (SW2) of the AND gate 325 is logic one, which turns on (closes) switches 360, 362, 365 and 367, and hence enables the first and second voltage dividers 350 and 355. As a result, the first and second voltage dividers 350 and 355 set the common-mode voltage at the inputs of the first test receiver 370. For example, if resistors R10 and R12 each have a resistance of 1 KΩ and resistors R11 and R13 each have a resistance of 2 KΩ, then the common-mode voltage is approximately equal to 0.67 VCC. In this example, the termination impedance for the test may be approximately equal to 1.67 KΩ, assuming resistors R8 and R9 each have a resistance of 1 KΩ. It is to be appreciated that the common-mode voltage of 0.67 VCC is exemplary, and that the first and second voltage dividers 350 and 355 may be configured to set the common-mode voltage to another voltage level (e.g., depending on a common-mode voltage level that optimizes performance of the first test receiver 370).

In this test mode, a test driver may transmit a differential pulse signal on the first and second signal paths 180 and 185. The signal may have a relatively low frequency (e.g., in the Megahertz range) compared with the high-speed data signal in the mission mode. The test driver may comprise the transmit driver 125 used to transmit data in the mission mode or a separate driver that is coupled to the first and second signal paths 180 and 185 and used for testing purposes.

In this embodiment, the onboard AC-coupling capacitors Cp and Cm may allow the test signal from the test driver to pass and reshape the pulses of the test signal. For example, each capacitor Cp and Cm may reshape a positive pulse into a signal that rises to a certain voltage level and then decays, in which the decay time depends on the capacitance of the capacitor. Thus, the test engine 385 may determine whether one or more of the onboard AC-coupling capacitors Cp and Cm are present (i.e., not missing) by observing the shapes (waveforms) of the signals received by the first test receiver 370. If the shapes of the received signals exhibit the rises and/or decays expected from the presence of the onboard AC-coupling capacitors Cp and Cm, then the test engine 385 may determine that the AC-coupling capacitors Cp and Cm are present. However, if the shapes of the received signals do not exhibit the expected rises and/or decays or no signal is received, then the test engine 385 may determine that one or more of the capacitors Cp and Cm are missing according to, for example, the JTAG 1149.6 standard or another JTAG standard.

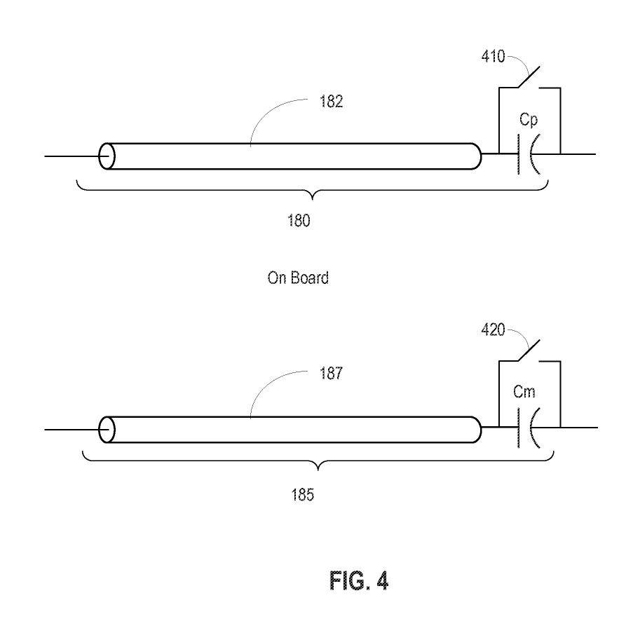

This test mode may also be used to detect an open in one or more of the onboard signal channels 182 and 187 (e.g., board traces). To test the channels 182 and 187, the onboard capacitors Cp and Cm may be temporarily shorted. This may be accomplished, for example, by bypassing the onboard AC-coupling capacitors Cp and Cm using bypass switches 410 and 420, an example of which is shown in FIG. 4. In this example, the switches 410 and 420 may be closed to test the channels 182 and 187. With the capacitors Cp and Cm temporarily shorted, one or more of the channels 182 and 187 may be driven with a test signal (e.g., differential test signal). The test engine 385 may detect an open in one or more of the channels 182 and 187 if the first test receiver 370 fails to receive the test signal on one or more of the channels 182 and 187. The test engine 385 may determine that there is no open in the channels 182 and 187 if the test signal is received on both channels 182 and 187. After the channels are tested, the bypass switches 410 and 420 may be opened.

In one aspect, the channels 182 and 187 may be tested to isolate a defect to one or more of the onboard capacitors Cp and Cm. For example, the test engine 385 may first perform an AC JTAG test with the bypass switches 410 and 420 open. If the test engine 385 detects an open, then the test engine 385 may determine whether the open is due to one or more missing onboard capacitors Cp and Cm or one or more opens in the channels 182 and 187 by performing a test with the bypass switches 410 and 420 closed. If the test engine 385 does not detect an open with the bypass switches 410 and 420 closed, then the test engine 385 may determine that the open is due to one or more missing onboard capacitors Cp and Cm.

DC JTAG Test Mode

This test mode may be used to detect defects in the signal paths 180 and 185, such as a short in one of the onboard AC-coupling capacitors Cp and Cm. In this test mode, the controller 392 sets signals en_acjtag and en_decmode to logic one and sets each of signals en_highz, en_gpio and en_byp to logic zero. As a result, the output (SW1) of the NOR gate 320 is logic zero, which turns off (opens) switches 230 and 235, and hence turns off the 50-ohm termination impedance of the receiver. The output (SW2) of the AND gate 325 is logic zero, which turns off (opens) switches 360, 362, 365 and 367, and hence disables the first and second voltage dividers 350 and 355.

In this test mode, a test driver may transmit one or more DC signals on the first and second signal paths 180 and 185. For example, to determine whether AC-coupling capacitor Cp is shorted, the driver may drive the first signal path 180 with a DC signal. If the onboard AC-coupling capacitor Cp is shorted, then the DC signal will go through the first signal path 180 to the first test receiver 370. If the onboard AC-coupling capacitor Cp is functional, then the capacitor Cp with block the DC signal. Thus, the test engine 385 may determine that the onboard AC-coupling capacitor Cp is shorted if the DC signal is received by the first test receiver 370. The other onboard AC-coupling capacitor Cm may be tested in a similar manner by driving a DC signal on the second signal path 185.

DC ATE Test Mode

This test mode may be used to detect defects in the signal paths 180 and 185, such as an open in one or more of the channels 182 and 187. In this test mode, the controller 392 sets signals en_acjtag and en_decmode to logic one and sets each of signals en_highz, en_gpio and en_byp to logic zero. As a result, the output (SW1) of the NOR gate 320 is logic zero, which turns off (opens) switches 230 and 235, and hence turns off the 50-ohm termination impedance of the receiver. The output (SW2) of the AND gate 325 is logic zero, which turns off (opens) switches 360, 362, 365 and 367, and hence disables the first and second voltage dividers 350 and 355

In this test mode, a test driver may transmit one or more DC signals on the first and second signal paths 180 and 185. The test driver may be an external driver temporarily coupled to the drive end of the signal paths 180 and 185 for testing purposes. To perform this test, the first and second channels 182 and 187 (e.g., onboard traces) may be DC-coupled to the receiver 310. This may be accomplished, for example, by bypassing the onboard AC-coupling capacitors Cp and Cm using the bypass switches 410 and 420 shown in FIG. 4. In this example, the switches 410 and 420 may be closed during a DC test and may be open during an AC test or the mission mode. It is to be appreciated that the AC-coupling capacitors Cp and Cm may be bypassed using other techniques.

As discussed above, this test mode may be used to detect an open in one or more of the channels 182 and 187 (e.g., board traces). For example, to determine whether there is an open in the first channel 182, the test driver may drive the first signal path 180 with a DC signal with the second signal path 185 at approximately ground. The DC signal may have a voltage that is above half VCC. In this example, the test engine 385 may detect an open in the first channel 182 if the first test receiver 370 or the second receiver 375 does not receive the DC signal. The duration of this test may be relatively short (e.g., a few microseconds).

In another example, to determine whether there is an open in the second channel 187, the test driver may drive the second signal path 185 with a DC signal with the first signal path 180 at approximately ground. The DC signal may have a voltage that is above half VCC. In this example, the test engine 385 may detect an open in the second channel 187 if the first test receiver 370 or the second test receiver 375 does not receive the DC signal. The duration of this test may be relatively short (e.g., a few microseconds).

In this mode, the test engine 385 may also detect a defect in which the first and second channels 182 and 187 are shorted together by detecting when the voltage difference between the two inputs of the first test receiver 370 is approximately zero volts.

GPIO Test Mode

This test mode may be used to detect defects in the I/O pads 172 and 174. In this mode, the controller 392 sets signal en_gpio to logic one and sets each of signals en_acjtag, en_decmode, en_highz and en_byp to logic zero. As a result, the output (SW1) of the NOR gate 320 is logic zero, which turns off (opens) switches 230 and 235, and hence turns off the 50-ohm termination impedance of the receiver. The output (SW2) of the AND gate 325 is logic zero, which turns off (opens) switches 360, 362, 365 and 367, and hence disables the first and second voltage dividers 350 and 355.

In this test mode, a test driver may be DC-coupled to the I/O pads 172 and 174 and transmit one or more DC signals to the I/O pads. To detect a defect of I/O pad 172, the test driver may transmit a DC signal to I/O pad 172 with I/O pad 174 at approximately ground. The DC signal may have a voltage approximately equal to VCC. In this example, the test engine 385 may detect an open at I/O pad 172 if the second test receiver 375 does not receive the DC signal. To detect a defect of I/O pad 174, the test driver may transmit a DC signal to I/O pad 174 with I/O pad 172 at approximately ground. The DC signal may have a voltage approximately equal to VCC. In this example, the test engine 385 may detect an open at I/O pad 174 if the second test receiver 375 does not receive the DC signal.

Bypass Test Mode

This test mode may be used to detect defects in the I/O pads 172 and 174 and termination resistors R0 and R1, as discussed further below. In this mode, the controller 392 sets signal en_byp to logic one and sets each of signals en_acjtag, en_decmode, en_highz and en_gpio to logic zero. As a result, the output (SW1) of the NOR gate 320 is logic one, which turns on (closes) switches 230 and 235, and hence turns on the 50-ohm termination impedance of the receiver. The output (SW2) of the AND gate 325 is logic zero, which turns off (opens) switches 360, 362, 365 and 367, and hence disables the first and second voltage dividers 350 and 355.

In this test mode, a test driver may be DC-coupled to the I/O pads 172 and 174 and drive one or more of the I/O pads with a current. To detect a defect of I/O pad 172 and/or termination resistor R0, the test driver may drive I/O pad 172 with a current with I/O pad 174 approximately at ground. If termination resistor R0 is properly connected to I/O pad 172, then the current flows through termination resistor R0 to ground. This produces a voltage across termination resistor R0, which is input to test path NP. The voltage may be relatively low, for example, between 100 mV and 400 mV, which translates into a common-mode voltage of between 50 mV and 200 mV.

In this example, the test engine 385 determines the voltage level received by the third test receiver 380 on test path NP and compares the voltage level to a target voltage, which may be approximately equal to the expected voltage across termination resistor R0 if termination resistor R0 is properly connected to I/O pad 172. If the voltage level is much higher than the target voltage, then the test engine 385 may determine there is an open between I/O pad 172 and termination resistor R0. This is because such an open prevents current from flowing through termination resistor R0. In this case, the high voltage level is due to the fact that the input impedance is much higher without termination resistor R0. If the voltage level is much lower than the target voltage, then the test engine 385 may determine there is an open at I/O pad 172. This is because such an open blocks the signal from the test driver. If the voltage level is at or close to the target voltage, then the test engine 385 may determine that there is no defect at I/O pad 172 or termination resistor R0.

To detect a defect of I/O pad 174 and/or termination resistor R1, the test driver may drive I/O pad 174 with a current with I/O pad 172 approximately at ground. If termination resistor R1 is properly connected to I/O pad 174, then the current flows through termination resistor R1 to ground. This produces a voltage across termination resistor R1, which is input to test path NM. The voltage may be relatively low, for example, between 100 mV and 400 mV, which translates into a common-mode voltage of between 50 mV and 200 mV.

In this example, the test engine 385 determines the voltage level received by the third test receiver 380 on test path NP and compares the voltage level to a target voltage, which may be approximately equal to the expected voltage across termination resistor R1 if termination resistor R1 is properly connected to I/O pad 174. If the voltage level is much higher than the target voltage, then the test engine 385 may determine there is an open between I/O pad 174 and termination resistor R1. If the voltage level is much lower than the target voltage, then the test engine 385 may determine there is an open at I/O pad 174. If the voltage level is at or close to the target voltage, then the test engine 385 may determine that there is no defect at I/O pad 174 or termination resistor R1.

In the high-impedance mode, signal en_highz may be set to logic one and each of signals en_acjtag, en_decmode, en_gpio, and en_byp may be set to logic zero. As a result, the output (SW1) of the NOR gate 320 is logic zero, which turns off (opens) switches 230 and 235, and hence turns off the 50-ohm termination impedance of the receiver. The output (SW2) of the AND gate 325 is logic zero, which turns off (opens) switches 360, 362, 365 and 367, and hence disables the first and second voltage dividers 350 and 355. As a result, the receiver 310 has a high input impedance in this mode.

In the mission mode (functional mode), each of signals en_acjtag, en_decmode, en_highz, en_gpio, and en_byp may be set to logic zero. As a result, the output (SW1) of the NOR gate 320 is logic one, which turns on (closes) switches 230 and 235, and hence turns on the 50-ohm termination impedance of the receiver. The output (SW2) of the AND gate 325 is logic zero, which turns off (opens) switches 360, 362, 365 and 367, and hence disables the first and second voltage dividers 350 and 355.

In the mission mode, the receiver 310 may receive a high-speed differential data signal from the transmitter 120 over the first and second signal paths 180 and 185 (shown in FIG. 1). On-chip AC-coupling capacitors C0 and C1 couple the AC component of the received signal to the inputs of the receive amplifier 255, which amplifies the signal and outputs the amplified signal to components (e.g., deserializer for a SERDES system) on the second chip 150 for further processing. Also, in the mission mode, the common-mode generator 252 provides an internal common-mode voltage to properly bias the inputs of the receive amplifier 255 to achieve good amplifying performance.

When the control circuit 390 configures the test circuit 315 and receive circuit 312 for a particular test mode, the controller 392 may communicate the test mode to the test engine 385 so that the test engine 385 performs the appropriate test. It is to be appreciated that the control circuit 390 is not limited to the exemplary implementation shown in FIG. 3, and that the control circuit 390 may be implemented using other logic gates that are arranged to perform one or more of the functions of the control circuit 390 described herein. Further, although switches 230, 235, 360, 362, 365 and 367 are shown separately from the control circuit 390 in FIG. 3, it is to be appreciated that these switches may be considered part of the control circuit 390. It is also to be appreciated that embodiments of the present disclosure are not limited to the exemplary test modes described herein.

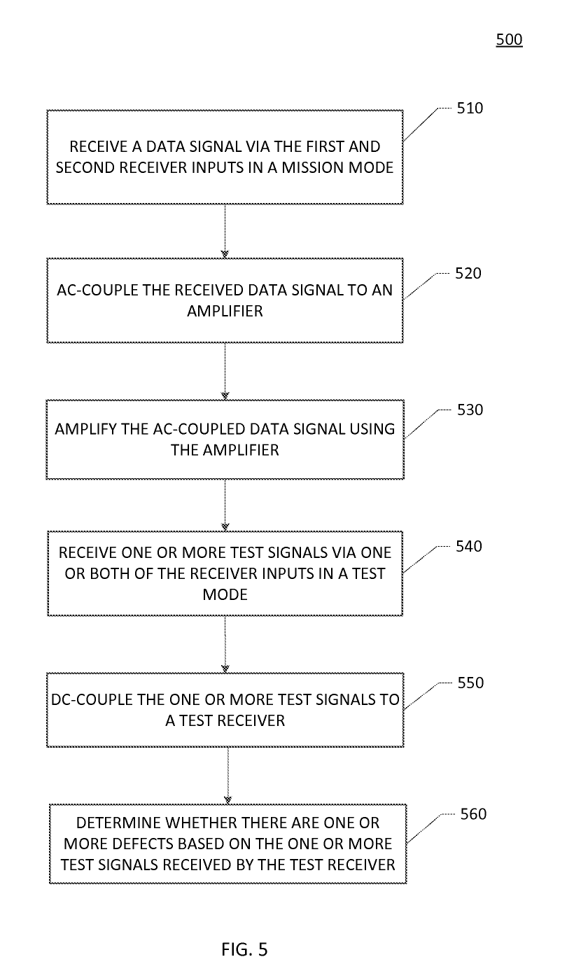

FIG. 5 is a flowchart of a method 500 for operating a receiver having a first receiver input and a second receiver input according to an embodiment of the present disclosure. The receiver may be the receiver 310 in FIG. 3 or other receiver with a built-in test structure.

In step 510, a data signal is received via the first and second receiver inputs in a mission mode. For example, the data signal may comprise a high-speed differential data signal comprising a first signal received by the first receiver input and a second signal (e.g., complement of the first signal) received by the second receiver input.

In step 520, the received data signal is AC coupled to an amplifier. For example, the data signal may be AC coupled to the amplifier (e.g., receive amplifier 255) by on-chip AC-coupling capacitors (e.g., capacitors C0 and C0. In step 530, the AC-coupled data signal is amplified using the amplifier.

In step 540, one or more test signals are received via one or both of the first and second receiver inputs in a test mode. For example, the one or more test signals may comprise one or more DC signals, one or more pulse signals, etc. The test mode may be any one of the exemplary test modes discussed above.

In step 550, the received one or more test signals is DC-coupled to a test receiver. In other words, the one or more test signals may be coupled to the test receiver without the use of AC-coupling capacitors. The test receiver may comprise any one of the exemplary test receivers discussed above.

In step 560, a determination is made whether there are one or more defects based on the one or more test signals received by the test receiver. For example, the one or more detects may comprise a missing onboard capacitor (e.g., capacitor Cp or Cm), a short, an open (e.g., open at an I/O pad), a missing connection between a receive path and a termination resistor (e.g., termination resistor R0 or R1), and/or other detect.

The test engine 385 and control circuit 390 according to embodiments of the present disclosure may be implemented with a general-purpose processor, a digital signal processor (DSP), an application specific integrated circuit (ASIC), a field programmable gate array (FPGA) or other programmable logic device, discrete hardware components, or any combination thereof designed to perform the functions described herein. A general-purpose processor may be a microprocessor, but in the alternative, the processor may be any conventional processor, controller, microcontroller, or state machine. A processor may perform the functions described herein by executing software comprising code for performing the functions. The software may be stored on a computer-readable storage medium, such as a RAM, a ROM, an EEPROM, an optical disk, and/or a magnetic disk.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A receiver, comprising:
an amplifier having a first input and a second input;
a first AC-coupling capacitor coupled between a first receiver input and the first input of the amplifier;
a second AC-coupling capacitor coupled between a second receiver input and the second input of the amplifier;
a test receiver having a first input and a second input, wherein the first input of the test receiver is coupled between the first receiver input and the first AC-coupling capacitor, and the second input of the test receiver is coupled between the second receiver input and the second AC-coupling capacitor; and
a test engine coupled to the test receiver;
wherein, in a test mode, the test receiver is configured to receive one or more test signals via one or both of the first and second receiver inputs, and the test engine is configured to determine whether there are one or more defects based on the one or more test signals received by the test receiver;
wherein, in a mission mode, the amplifier is configured to receive a data signal via the first and second receiver inputs and amplify the received data signal.

2. The receiver of claim 1, further comprising:
a first resistor coupled between the first receiver input and the first input of the test receiver; and
a second resistor coupled between the second receiver input and the second input of the test receiver.

3. The receiver of claim 2, further comprising:
a first charged device model (CDM) device coupled between the first resistor and the first input of the test receiver;
and a second CDM device coupled between the second resistor and the second input of the test receiver.

4. The receiver of claim 1, further comprising:
a first voltage divider;
a second voltage divider, wherein the first and second voltage dividers are configured to set a common-mode voltage at the first and second inputs of the test receiver; and
a control circuit configured to selectively enable and disable the first and second voltage dividers, wherein the control circuit enables the first and second voltage dividers in the test mode, and disables the first and second voltage dividers in the mission mode.

5. The receiver of claim 1, further comprising:
a first termination resistor having a first end coupled to the first receiver input, and a second end;
a second termination resistor having a first end coupled to the second receiver input, and a second end; and
a control circuit configured to selectively couple and decouple the second ends of the first and second termination resistors to a ground, wherein the control circuit couples the second ends of the first and second termination resistors to the ground in the mission mode, and decouples the first and second termination resistors from the ground in the test mode.

6. The receiver of claim 5, wherein each of the first and second termination resistors has a resistance approximately equal to 50 ohms.

7. A receiver, comprising:
an amplifier having a first input coupled to a first receiver input and a second input coupled to a second receiver input;
a first test receiver having a first input coupled to the first receiver input and a second input coupled to the second receiver input;
a second test receiver having a first input coupled to the first receiver input and a second input coupled to the second receiver input; and
a test engine coupled to the first and second test receivers;
wherein, in a first test mode, the first test receiver is configured to receive one or more first test signals via one or both of the first and second receiver inputs, and the test engine is configured to determine whether there are one or more first defects based on the one or more first test signals received by the first test receiver;
wherein, in a second test mode, the second test receiver is configured to receive one or more second test signals via one or both of the first and second receiver inputs, and the test engine is configured to determine whether there are one or more second defects based on the one or more second test signals received by the second test receiver;
wherein, in a mission mode, the amplifier is configured to receive a data signal via the first and second receiver inputs and amplify the received data signal.

8. The receiver of claim 7, further comprising:
a first voltage divider;
a second voltage divider, wherein the first and second voltage dividers are configured to set a common-mode voltage at the first and second inputs of the first test receiver; and
a control circuit configured to selectively enable and disable the first and second voltage dividers, wherein the control circuit enables the first and second voltage dividers in the first test mode, and disables the first and second voltage dividers in the second test mode and the mission mode.

9. The receiver of claim 8, wherein, in the first test mode, the test engine is configured to determine whether there is a defect in a signal path coupled to the first receiver input, wherein the signal path is on a board.

10. The receiver of claim 9, wherein the defect in the signal path comprises a missing onboard capacitor, a shorted onboard capacitor, or an open in the signal path.

11. The receiver of claim 9, wherein, in the second test mode, the test engine is configured to determine whether there is a defect of an input/output pad or a defect of a termination resistor.

12. The receiver of claim 7, further comprising:
a first termination resistor having a first end coupled to the first receiver input, and a second end;
a second termination resistor having a first end coupled to the second receiver input, and a second end; and
a control circuit configured to selectively couple and decouple the second ends of the first and second termination resistors to a ground, wherein the control circuit couples the second ends of the first and second termination resistors to the ground in the mission mode and the second test mode, and decouples the first and second termination resistors from the ground in the first test mode.

13. The receiver of claim 12, wherein, in the first test mode, the test engine is configured to determine whether there is a defect in a signal path coupled to the first receiver input, wherein the signal path is on a board.

14. The receiver of claim 13, wherein the defect in the signal path comprises a missing onboard capacitor, a shorted onboard capacitor, or an open in the signal path.

15. The receiver of claim 13, wherein, in the second test mode, the test engine is configured to determine whether there is a defect of the first termination resistor or a defect of the second termination resistor.

16. The receiver of claim 7, further comprising:
a first AC-coupling capacitor coupled between the first receiver input and the first input of the amplifier; and
a second AC-coupling capacitor coupled between the second receiver input and the second input of the amplifier.

17. A method for operating a receiver having a first receiver input and a second receiver input, the method comprising:
receiving a data signal via the first and second receiver inputs in a mission mode;
AC-coupling the received data signal to an amplifier;
amplifying the AC-coupled data signal using the amplifier;
receiving one or more test signals via one or both of the first and second receiver inputs in a test mode;
DC-coupling the received one or more test signals to a test receiver; and
determining whether there are one or more defects based on the one or more test signals received by the test receiver.

18. The method of claim 17, wherein determining whether there are one or more defects comprises determining whether there is a defect in a signal path coupled to the first receiver input, wherein the signal path is on a board.

19. The method of claim 18, wherein the defect of the signal path comprises a missing onboard capacitor, a shorted onboard capacitor, or an open in the signal path.

20. The method of claim 17, wherein the receiver comprises a first voltage divider, and a second voltage divider, wherein the first and second voltage dividers are configured to set an input common-mode voltage of the test receiver, and wherein the method further comprises:
enabling the first and second voltage dividers in the test mode; and
disabling the first and second voltage dividers in the mission mode.

21. The method of claim 17, wherein the receiver comprises a first termination resistor having a first end coupled to the first receiver input, and second termination resistor having a first end coupled to the second receiver input, wherein the method further comprises:
coupling second ends of the first and second termination resistors to a ground in the mission mode; and
decoupling the second ends of the first and second termination resistors from the ground in the test mode.

22. The method of claim 21, wherein each of the first and second termination resistors comprises a resistance of 50 ohms.

23. An apparatus for operating a receiver having a first receiver input and a second receiver input, apparatus comprising:
means for receiving a data signal via the first and second receiver inputs in a mission mode;
means for AC-coupling the received data signal to an amplifier;
means for receiving one or more test signals via one or both of the first and second receiver inputs in a test mode;
means for DC-coupling the received one or more test signals to a test receiver;
means for determining whether there are one or more defects based on the one or more test signals received by the test receiver.

24. The apparatus of claim 23, wherein the means for determining whether there are one or more defects comprises means for determining whether there is a defect in a signal path coupled to the first receiver input, wherein the signal path is on a board.

25. The apparatus of claim 24, wherein the defect in the signal path comprises a missing onboard capacitor, a shorted onboard capacitor, or an open in the signal path.

26. The apparatus of claim 23, wherein the receiver comprises a first voltage divider, and a second voltage divider, wherein the first and second voltage dividers are configured to set an input common-mode voltage of the test receiver, and wherein the apparatus further comprises:
means for enabling the first and second voltage dividers in the test mode; and
means for disabling the first and second voltage dividers in the mission mode.

27. The apparatus of claim 23, wherein the receiver comprises a first termination resistor having a first end coupled to the first receiver input, and second termination resistor having a first end coupled to the second receiver input, wherein the apparatus further comprises:
means for coupling second ends of the first and second termination resistors to a ground in the mission mode; and
means for decoupling the second ends of the first and second termination resistors from the ground in the test mode.

28. The apparatus of claim 27, wherein each of the first and second termination resistors comprises a resistance of 50 ohms.
